(19) United States
(12) Patent Application Publication
(10) Pub. No.: US 2019/0353467 A1
(43) Pub. Date: Nov. 21, 2019

(54) LOW COST CHIP SLAPPER DETONATOR

(71) Applicant: LAWRENCE LIVERMORE NATIONAL SECURITY, LLC, Livermore, CA (US)

(72) Inventors: Connor M. West, Livermore, CA (US); Dat Q. Le, Livermore, CA (US)

(21) Appl. No.: 15/982,580

(22) Filed: May 17, 2018

(51) Int. Cl. F42B 3/198; C25D 7/00; C25D 3/48; C23C 14/30; C23C 14/18; C23C 14/04; C25D 5/02

(52) U.S. Cl. CPC F42B 3/198; C25D 7/00; C25D 3/48; C25D 5/02; C23C 14/18; C23C 14/042; C23C 14/30

(57) ABSTRACT

A method of making a low cost chip slapper detonator includes the steps of: providing a substrate having a substrate top and a substrate bottom; electroplating a pattern of conductive pads on the substrate bottom; drilling a pattern of via holes through the substrate, wherein the via holes are in contact with the conductive pads; plating the via holes with a conductive material to create a conductive path in the via holes between the substrate top and the substrate bottom; metallization of a multiplicity of conductive bridges on the substrate top; adhering a slapper layer over the multiplicity conductive bridges on the substrate; and dicing the substrate into individual chip slapper detonators wherein each the individual chip slapper detonator includes one of the multiplicity conductive bridges.

### STATEMENT AS TO RIGHTS TO APPLICATIONS MADE UNDER FEDERALLY SPONSORED RESEARCH AND DEVELOPMENT

The United States Government has rights in this application pursuant to Contract No. DE-AC52-07NA27344 between the United States Department of Energy and Lawrence Livermore National Security, LLC for the operation of Lawrence Livermore National Laboratory.

### BACKGROUND

### Field of Endeavor

The present application relates generally to devices for setting off an explosive charge and more particularly to a low cost chip slapper detonator.

### State of Technology

This section provides background information related to the present disclosure which is not necessarily prior art.

United States Published Patent Application No. 2013/0284043 for a silver bridge element slapper detonator provides the state of technology information reproduced below.

Slapper detonators are used to initiate explosives for commercial and other applications. Slapper detonators are a class of detonators that has been capturing a larger and larger share of the detonator market. The value of slapper detonators is found in the fact that these detonators can be made to fire at low energies and yet remain safe due to the unique firing requirements. Paragraph [0005]
High Voltage Detonators contain small “bridges” that are exploded by the high current pulse from the fireset. The bridges can be made of different materials, but the best performance is generally achieved by the best conductors. The four best conductors are in rank order, silver, copper, gold and aluminum. Early designs that required the bridgewire to be in contact with the explosive used gold because it is highly resistant to chemical attack. silver, due to its high suscepti-bility to chemical attack, was rejected early for this application. Paragraph [0006]
Slapper detonators operate by using the exploding bridge to propel a small plastic insulating layer or “flyer” into the explosive. Because the bridge is no longer in contact with the explosive, other materials besides gold can and have been used. Silver, however, has never been tried in a slapper appli-cation, perhaps due to the early rejection. Paragraph [0007]

U.S. Pat. No. 6,470,802 for a multilayer chip slapper provides the state of technology information reproduced below.

Chip slapper type detonators in general cause a “flying plate” to be propelled at a high velocity against a secondary explosive medium creating a shock wave which results in the detonation of the secondary explosive. In a typical design, there are two wide area conductive lands separated by a narrow rectangular bridge member. The lands are connected to a capacitor through a high voltage switch. When the switch closes, the capacitor provides current across the lands which vaporizes the bridge member turning into a plasma. This plasma accelerates a portion of the dielectric material covering the bridge member to a high velocity, causing it to slap into an explosive. The resulting shock wave causes detonation of the explosive.
Traditional chip slappers include a ceramic substrate and a copper conductive layer on one surface of the substrate in the shape of the two wide lands separated by the narrow bridge portion. There may be a protective gold coating on the copper to prevent the copper conductive layer from corroding and to enhance electrical connections made to the lands. A flyer layer made of polyimide is then secured over the bridge portion.
There are several potential problems associated with this current design. First, the flyer layer does not exhibit an affinity for the gold coating and may not properly stick in place on the bridge portion. Second, the gold of the coating can migrate into the copper of the conductive layer and vice versa. The result is that the gold coating loses its corrosion prevention ability and its ability to enhance the electrical connections to the lands. Also, when the copper material migrates into the gold, there is a higher susceptibility to corrosion.

### SUMMARY

Features and advantages of the disclosed apparatus, systems, and methods will become apparent from the following description. Applicant is providing this description, which includes drawings and examples of specific embodiments, to give a broad representation of the apparatus, systems, and methods. Various changes and modifications within the spirit and scope of the application will become apparent to those skilled in the art from this description and by practice of the apparatus, systems, and methods. The scope of the apparatus, systems, and methods is not intended to be limited to the particular forms disclosed and the application covers all modifications, equivalents, and alternatives falling within the spirit and scope of the apparatus, systems, and methods as defined by the claims.

The inventors' apparatus, systems, and methods provide a low cost chip slapper including a substrate with a conductive bridge layer and a flyer layer on one side of the substrate. The other side of the substrate consists of conductive pads. The bridge side of the substrate is electrically connected to the pad side of the substrate through a conductive pathway. The design and shape of the conductive bridge is manufactured using a masked physical vapor deposition process. The flyer layer is applied using a lamination technique. The inventors provide a method of making chip slapper detonators. The method includes the steps of: providing a substrate having a substrate top and a substrate bottom; electroplating a pattern of conductive pads on the substrate bottom; drilling a pattern of via holes through the substrate, wherein the via holes are in contact with the conductive pads; plating the via holes with a conductive material to create a conductive path in the via holes between the substrate top and the substrate bottom; metallization of a multiplicity of conductive bridges on the substrate top; adhering a slapper layer over the multiplicity conductive bridges on the substrate; and dicing the substrate into individual chip slapper detonators wherein each the individual chip slapper detonator includes one of the multiplicity conductive bridges.

The inventors' low cost chip slapper uses a vapor deposition process to create a substrate with a conductive bridge layer on one side. The bridge layer is designed with two wide ends connected by a narrow bridge. When electricity flows through it, the concentrated energy flowing across the narrow bridge is enough to vaporize the metal. The vaporized bridge propels a “slapper” from the flyer layer and shock initiates the next stage high explosive. Absent the electrical current the detonator is physically separated from the high explosive. This separation provides additional safety from external factors accidentally igniting the material.

The inventors' low cost chip slapper includes the following four elements:

First, is the production of the substrate. The substrate is a custom made alumina ceramic wafer. The bottom side of the wafer has a pattern of electroplated gold pads. A pattern of via holes are laser drilled and plated with gold to create a conductive pathway between the surfaces of the substrate.

The second element is the metallization of the conductive bridge to the top side of the substrate. A shadow mask is laser cut out of Kapton which establishes the pattern and shape of the conductive bridge. A machined “strongback” is machined to a similar but over sized pattern. The strongback is used to hold the Kapton mask flat during the vapor deposition process. The assembly is then run through an E-beam vapor deposition process to deposit the conductive bridge onto the surface of the substrate.

The third element is the application of the “slapper” layer. A layer of Kapton is adhered over the conductive bridge surface of the substrate using Pyralux adhesive. The lamination process is performed under vacuum.

Fourth, the wafer is diced into individual chip slappers.

One important benefit of the inventors' low cost chip slapper is the cost efficiency. Instead of etching, a Kapton mask is used to define the shape of the bridge. This mask process allows for the ability to easily customize the shape and size of the conductive bridge portion of the chip slapper. Additionally, through the inventors' preliminary testing they have seen increased performed in the chip slapper. Thus, the inventors' low cost chip slapper is delivering better performance at a lower cost.

The inventors' low cost chip slapper detonator has use in the shock initiation of explosives, mining, and explosive welding. The inventors' low cost chip slapper has significant value in stockpile stewardship and national security. There are also benefits to the commercial mining and oil and gas sectors. A safer detonator can allow HE manufacturers to package safer HE for the mining and oil and gas sectors.

The apparatus, systems, and methods are susceptible to modifications and alternative forms. Specific embodiments are shown by way of example. It is to be understood that the apparatus, systems, and methods are not limited to the particular forms disclosed. The apparatus, systems, and methods cover all modifications, equivalents, and alternatives falling within the spirit and scope of the application as defined by the claims.

### BRIEF DESCRIPTION OF THE DRAWINGS

The present application relates generally to devices for setting off an explosive charge and more particularly to a low cost chip slapper detonator.

The accompanying drawings, which are incorporated into and constitute a part of the specification, illustrate specific embodiments of the apparatus, systems, and methods and, together with the general description given above, and the detailed description of the specific embodiments, serve to explain the principles of the apparatus, systems, and methods.

FIG. 1A and FIG. 1B together provide a flow chart illustrating an embodiment of the inventors' apparatus, systems, and methods.

FIG. 2A is a partial view of the bottom surface of a substrate of the inventors' apparatus, systems, and methods.

FIG. 2B is a partial view of the top surface of a substrate of the inventors' apparatus, systems, and methods.

FIG. 2C is a partial view cross sectional view taken from FIG. 2B.

FIG. 2D is a partial view of a substrate and mask of the inventors' apparatus, systems, and methods.

FIG. 2E is a partial cross sectional view of the substrate and mask of the inventors' apparatus, systems, and methods.

FIG. 2F is a partial view of the substrate after being patterned with the bridges.

FIG. 2G is a partial view of the substrate with vapor deposited bridges showing a layer of Kapton slapper laminated onto the substrate/bridge.

FIG. 2H is a partial view of the fabricated chip slappers.

FIG. 2I is an illustrative example showing the substrate/wafer and the chip slappers.

FIG. 3A is a top view of one embodiment of a chip slapper of the inventors' apparatus, systems, and methods.

FIG. 3B is a side view of the chip slapper shown in FIG. 3A.

FIG. 4A is an illustration of another embodiment of a chip slapper of the inventors' apparatus, systems, and methods.

FIG. 4B is a side view of the embodiment of the chip slapper shown in FIG. 4A.

### DETAILED DESCRIPTION OF SPECIFIC EMBODIMENTS

Referring to the drawings, to the following detailed description, and to incorporated materials, detailed information about the apparatus, systems, and methods is provided including the description of specific embodiments. The detailed description serves to explain the principles of the apparatus, systems, and methods. The apparatus, systems, and methods are susceptible to modifications and alternative forms. The application is not limited to the particular forms disclosed. The application covers all modifications, equivalents, and alternatives falling within the spirit and scope of the apparatus, systems, and methods as defined by the claims.

There is a need for resilient detonators that perform in a range of environmental conditions. Such a technology can allow for the use of safer (insensitive High Explosives). Heat, humidity, ambient pressures and vibration are some of the external factors that can ignite explosives when unintended. The technical problem is to initiate secondary explosives in a safe and reliable manner. The benefit of an exploding foil initiator (EFI) is that it is not in direct contact with the explosive element and the flyer layer protects the conductive bridge from the environment. These aspects increase both the safety and reliability of the detonator. The current manufacturing method first deposits a conductive metal layer and then etches the metal layer to form a narrow bridge. The flyer layer is also deposited on, usually through spin coating of polyimide. These are both expensive processes.

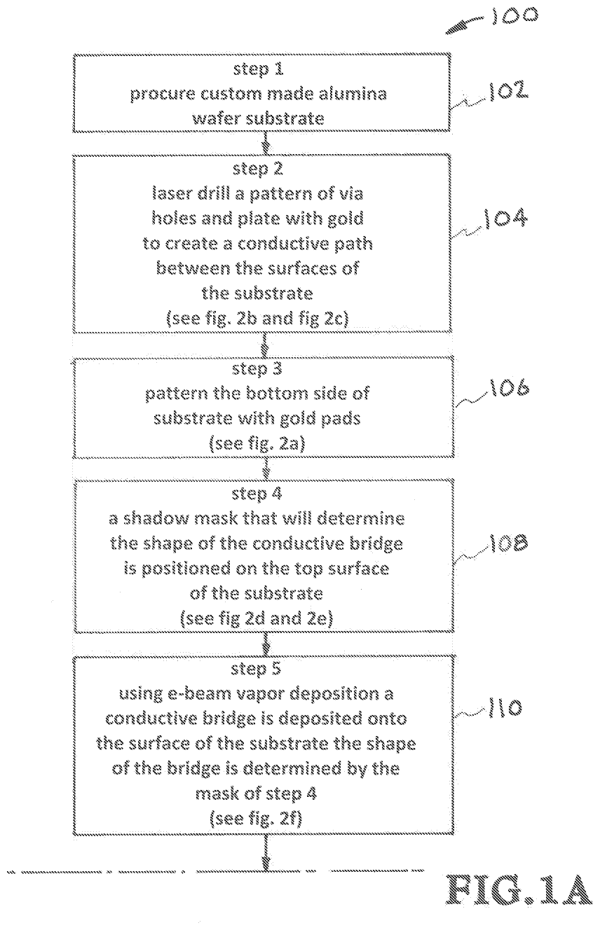

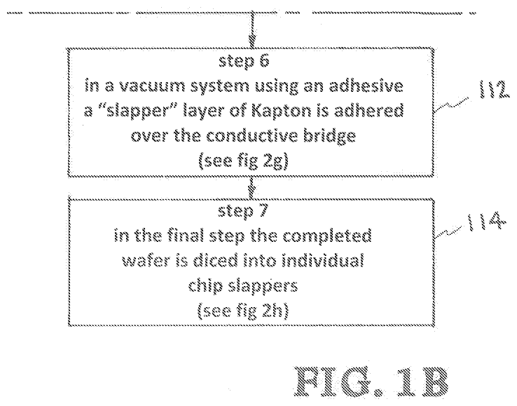

Referring now to the drawings, and in particular to FIG. 1A and FIG. 1B; an embodiment of the inventors' apparatus, systems, and methods are presented. The embodiment and the flow chart are designated generally by the reference numeral 100. The embodiment and flow chart 100 includes the components and steps listed below.

(101) Step 1—Procure custom made alumina wafer substrate;

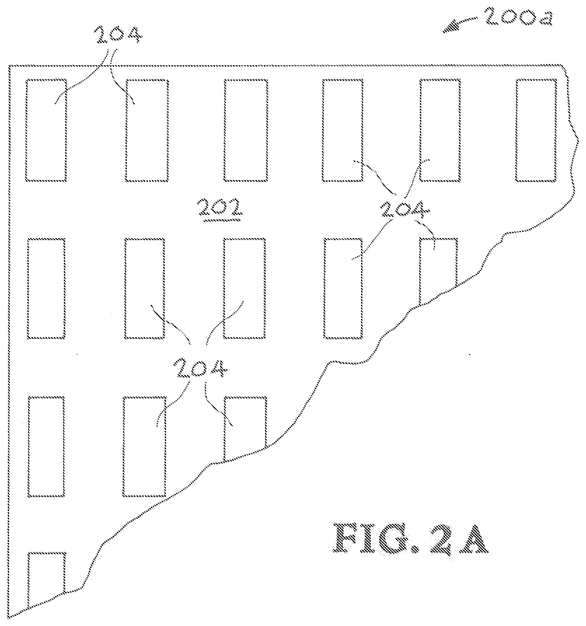

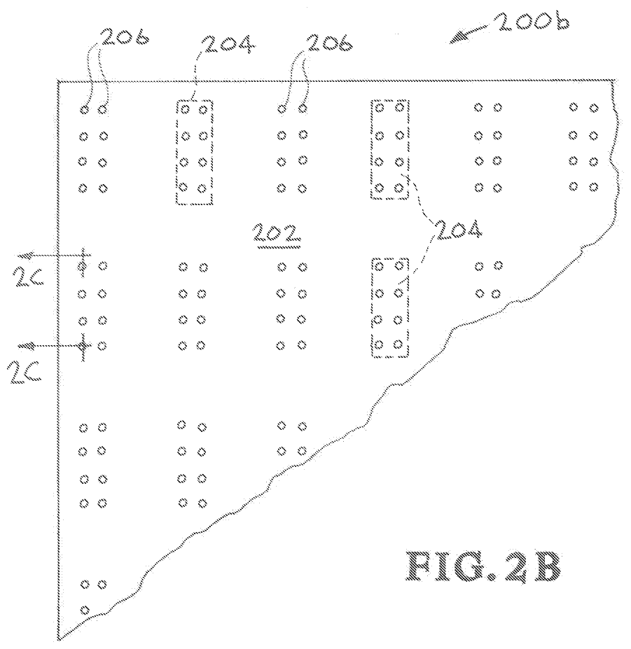

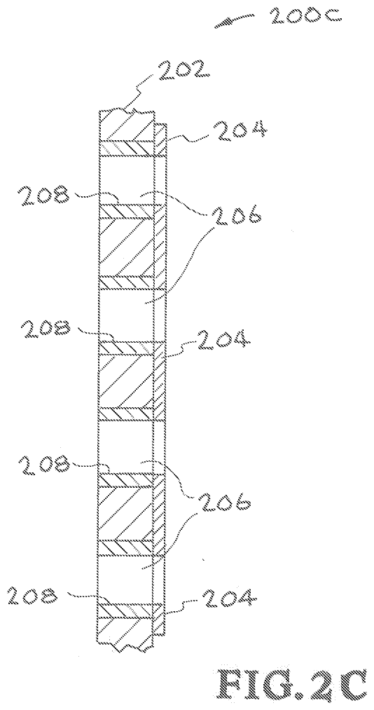

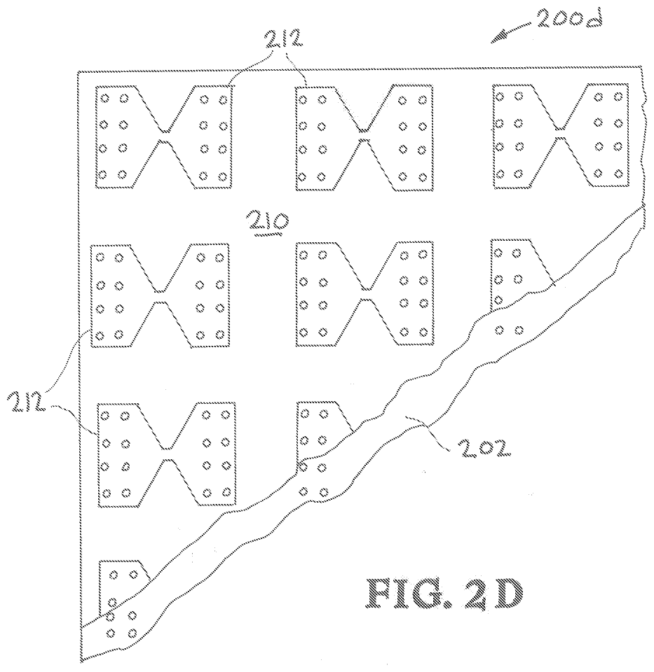

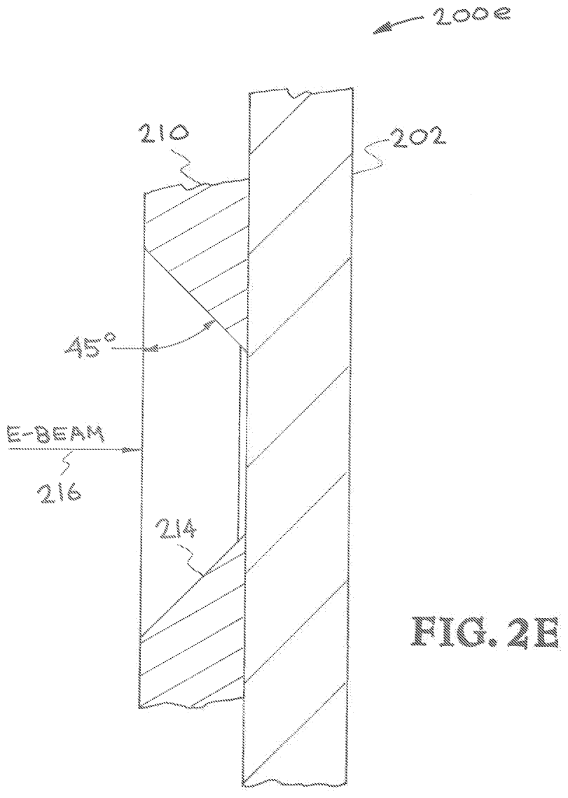

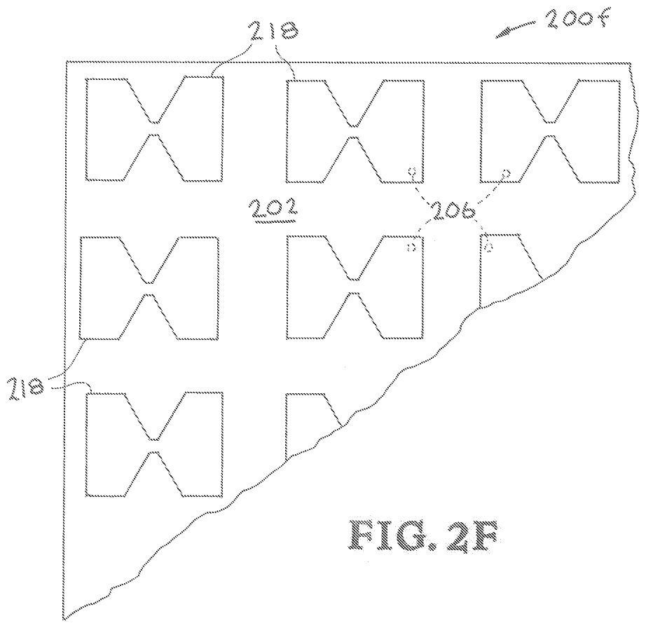

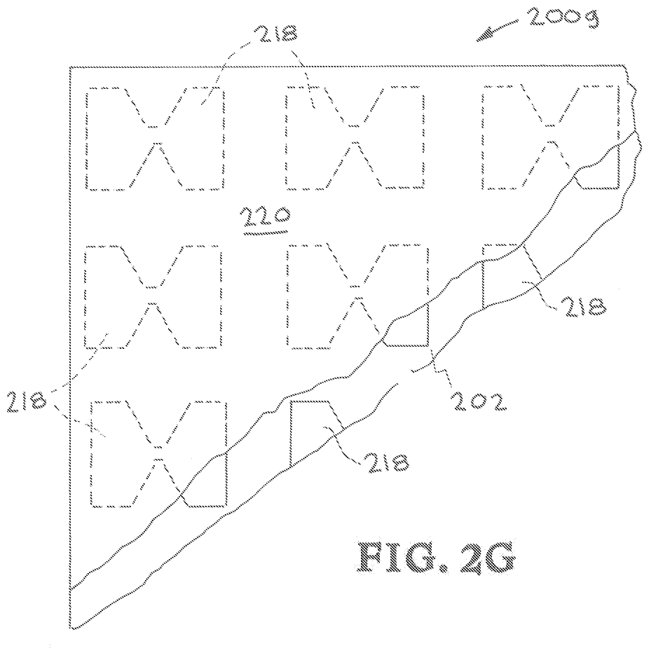

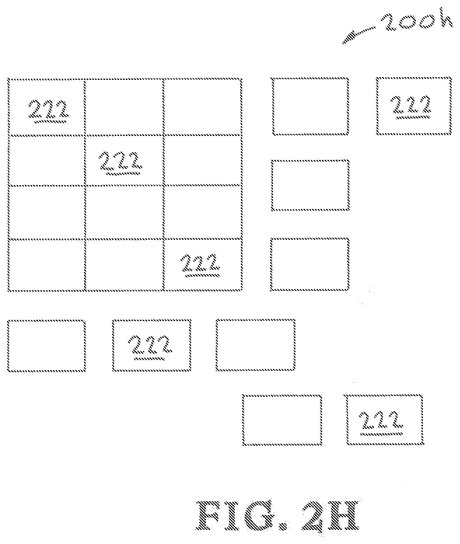

(102) Step 2—Laser drill a pattern of via holes and plate with gold to create a conductive path between the surfaces of the substrate (this step and component is further illustrated and described in FIG. 2B and FIG. 2C);

(103) Step 3—Pattern the bottom side of the substrate with gold pads (this step and component is further illustrated and described in FIG. 2A);

(104) Step 4—A shadow mask that will determine the shape of the conductive bridge is positioned on the top surface of the substrate (this step and component is further illustrated and described in FIG. 2D and FIG. 2E);

(105) Step 5—Using e-beam vapor deposition, a conductive bridge is deposited onto the surface of the substrate the shape of the bridge is determined by the mask of step 4 (this step and component is further illustrated and described in FIG. 2F);

(106) Step 6—In a vacuum system using an adhesive a “slapper” layer of Kapton is adhered over the conductive bridge (this step and component is further illustrated and described in FIG. 2G);

(107) Step 7—In the final step the completed wafer is diced into individual chip slappers (this step and component is further illustrated and described in FIG. 2H).

The components and steps of the flow chart 100 having been identified and described, the embodiment 100 of inventors' apparatus, systems, and methods will be described in greater detail. The inventors' apparatus, systems, and methods provide a low cost chip slapper including of a substrate with a conductive bridge layer and a flyer layer on one side of the substrate. The other side of the substrate consists of conductive pads. The bridge side of the substrate is electrically connected to the pad side of the substrate through a conductive pathway. The design and shape of the conductive bridge is manufactured using a masked physical vapor deposition process. The flyer layer is applied using a lamination technique.

The inventors' low cost chip slapper uses a vapor deposition process to create a substrate with a conductive bridge layer on one side. The bridge layer is designed with two wide ends connected by a narrow bridge. When electricity flows through it, the concentrated energy flowing across the narrow bridge is enough to vaporize the metal. The vaporized bridge propels a “slapper” from the flyer layer and shock initiates the next stage high explosive. Absent the electrical current the detonator is physically separated from the high explosive. This separation provides additional safety from external factors accidentally igniting the material.

The inventors' low cost chip slapper includes the following four elements:

First, is the production of the substrate. The substrate is a custom made alumina ceramic wafer. The bottom side of the wafer has a pattern of electroplated gold pads. A pattern of via holes are laser drilled and plated with gold to create a conductive pathway between the surfaces of the substrate.

The second element is the metallization of the conductive bridge to the top side of the substrate. A shadow mask is laser cut out of Kapton which establishes the pattern and shape of the conductive bridge. A machined “strongback” is machined to a similar but over sized pattern. The strongback is used to hold the Kapton mask flat during the vapor deposition process. The assembly is then run through an E-beam vapor deposition process to deposit the conductive bridge onto the surface of the substrate.

The third element is the application of the “slapper” layer. A layer of Kapton is adhered over the conductive bridge surface of the substrate using Pyralux adhesive. The lamination process is performed under vacuum.

Fourth, the wafer is diced into individual chip slappers. One important benefit of the inventors' low cost chip slapper is the cost efficiency. Instead of etching, a Kapton mask is used to define the shape of the bridge. This mask process allows for the ability to easily customize the shape and size of the conductive bridge portion of the chip slapper. Additionally, through the inventors' preliminary testing they have seen increased performed in the chip slapper, Thus, the inventors' low cost chip slapper is delivering better performance at a lower cost.

Referring now to FIG. 2A through FIG. 2I, a sequence of illustrations further illustrates the embodiment 100 of the inventors' apparatus, systems, and methods. Referring to FIG. 2A, step 2 of the flow chart 100 is illustrated in greater detail. Step 2 is to pattern the bottom side of the substrate with gold pads. FIG. 2A is a partial view of the bottom surface of substrate 202. The partial view is designated generally by the reference numeral 200a. The substrate 202 in embodiment 100 is a custom made alumina ceramic wafer. In step 2 of the flow chart 100 the bottom side of the substrate 202 is patterned with conductive gold pads 204.

Referring to FIG. 2B, step 3 of the flow chart 100 is illustrated in greater detail. Step 3 is to laser drill a pattern of via holes and plate with gold to create a conductive path between the surfaces of the substrate.

FIG. 2B is a partial view of the top surface of substrate 202. The partial view is designated generally by the reference numeral 200b. The substrate 202 in embodiment 100 is a custom made alumina ceramic wafer. Step 3 of the flow chart 100 is to produce a pattern of via holes 206. The via holes 206 are laser drilled and plated with gold to create a conductive pathway between the surfaces of the substrate 202.

Referring to FIG. 2C, another illustration describes step 3 of the flow chart 100 in greater detail. Step 3 is to laser drill a pattern of via holes and plate with gold to create a conductive path between the surfaces of the substrate.

The FIG. 2C is a partial view cross sectional view taken from FIG. 2B. This partial view is designated generally by the reference numeral 200c. The partial view cross sectional view 200c shows via holes 206. The via holes 206 are connected to the conductive gold pads 204. The via holes 206 are plated with gold plating 208 to create a conductive pathway between the surfaces of the substrate 202.

Referring to FIG. 2D, an illustration describes step 4 of the flow chart 100 in greater detail. In step 4 a shadow mask that will determine the shape of the conductive bridge is positioned on the top surface of the substrate.

FIG. 2D is a partial view of the substrate 202. This partial view is designated generally by the reference numeral 200d. The partial view 200d shows a shadow mask 210. The shadow mask 210 is shown positioned on the top surface of substrate 202 in FIG. 2D. The shadow mask 210 will determine the shape 212 of vapor deposited bridges that will be added and will be shown in subsequent FIG. 2F.

Referring to FIG. 2E, an illustration that further describes step 4 of the flow chart 100. In step 4 a shadow mask will determine the shape of the conductive bridge. The shadow mask is positioned on the top surface of the substrate.

FIG. 2E is a partial cross sectional view of the substrate 202 and mask 210. This partial cross sectional view is designated generally by the reference numeral 200e. The partial view 200e shows an angled 45° cut 214 to prevent shadowing during the subsequent e-beam deposition of the bridges. The reference numeral 216 illustrates the direction of the e-beam.

Referring to FIG. 2F, an illustration that further describes step 5 of the flow chart 100. Step 5 is the use of e-beam vapor deposition wherein a conductive bridge is deposited onto the surface of the substrate and the shape of the bridge is determined by the mask of step 4.

FIG. 2F is a partial view of the substrate 202 after being patterned with the bridges 218. This partial view is designated generally by the reference numeral 200f. The partial view 200f shows the via holes 206 in the substrate 202 and the bridges 218.

Referring to FIG. 2G, an illustration that further describes step 6 of the flow chart 100. Step 6 is: in a vacuum system using an adhesive a “slapper” layer of Kapton that is adhered over the conductive bridge.

FIG. 2G is a partial view of the substrate 202 with vapor deposited bridges 218 showing a layer of Kapton slapper 220 laminated onto the substrate 202/bridge 218 structure. This partial view is designated generally by the reference numeral 200g.

Referring to FIG. 2H, an illustration that further describes step 7 of the flow chart 100. Step 7 is: in the final step the completed wafer is diced into individual chip slappers.

FIG. 2H is a partial view of the fabricated chip slappers 222. This partial view is designated generally by the reference numeral 200h. FIG. 2H shows the fabricated chip slappers 222 after the assembly has been scored for wafer dicing.

Referring to FIG. 2I, an illustration that further describes step 7 of the flow chart MU. Step 7 is: in the final step the completed wafer is diced into individual chip slappers.

FIG. 2I is an illustrative example showing the substrate/wafer and the chip slappers. This illustrative example view is designated generally by the reference numeral 200i. The areas shown with circles in them are where there would be chip slapper. The vacant areas are for use during the fabrication of chip slappers. The circles are for identification only.

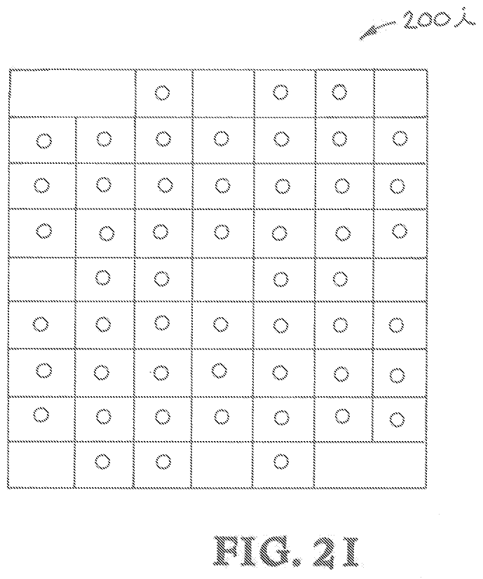

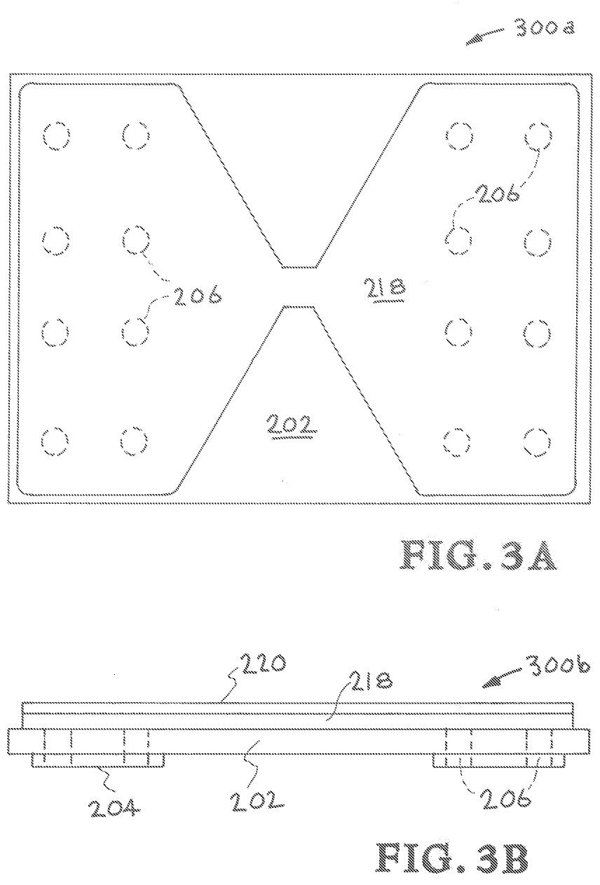

Referring to FIG. 3A, an illustration of one embodiment of a chip slapper is provided. FIG. 3A is a top view of one embodiment of a chip slapper. This top view is designated generally by the reference numeral 300a. The top view 300a shows the substrate 202, deposited bridges 218, and holes/vias 206.

Referring to FIG. 3B, a side view of the chip slapper of FIG. 3A is provided. This side view is designated generally by the reference numeral 300b. The side view 300b shows the substrate 202, bridge layer 218, holes/vias 206, and Kapton layer 220.

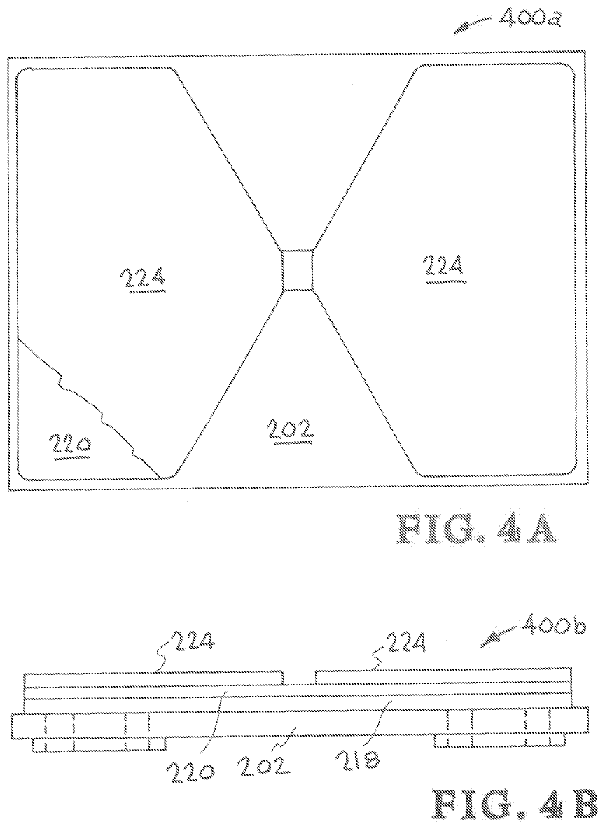

Referring to FIG. 4A, an illustration of another embodiment of a chip slapper is provided. FIG. 4A is a top view of one embodiment of a chip slapper. This top view is designated generally by the reference numeral 400a. The top view 400a shows the substrate 202, deposited bridges 218, holes/vias 206 and Kapton layer 220. An additional layer 224 of gold has been deposited over parts of the Kapton layer 220.

Referring to FIG. 4B, a side view of the embodiment of the chip slapper of FIG. 4A is provided. This side view is designated generally by the reference numeral 400b. The side view 400b shows the substrate 202, bridge layer 218, Kapton layer 220, and gold layer 224.

Although the description above contains many details and specifics, these should not be construed as limiting the scope of the application but as merely providing illustrations of some of the presently preferred embodiments of the apparatus, systems, and methods. Other implementations, enhancements and variations can be made based on what is described and illustrated in this patent document. The features of the embodiments described herein may be combined in all possible combinations of methods, apparatus, modules, systems, and computer program products. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination. Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described above should not be understood as requiring such separation in all embodiments.

Therefore, it will be appreciated that the scope of the present application fully encompasses other embodiments which may become obvious to those skilled in the art. In the claims, reference to an element in the singular is not intended to mean “one and only one” unless explicitly so stated, but rather “one or more.” All structural and functional equivalents to the elements of the above-described preferred embodiment that are known to those of ordinary skill in the art are expressly incorporated herein by reference and are intended to be encompassed by the present claims. Moreover, it is not necessary for a device to address each and every problem sought to be solved by the present apparatus, systems, and methods, for it to be encompassed by the present claims. Furthermore, no element or component in the present disclosure is intended to be dedicated to the public regardless of whether the element or component is explicitly recited in the claims. No claim element herein is to be construed under the provisions of 35 U.S.C. 112, sixth paragraph, unless the element is expressly recited using the phrase “means for.”

While the apparatus, systems, and methods may be susceptible to various modifications and alternative forms, specific embodiments have been shown by way of example in the drawings and have been described in detail herein. However, it should be understood that the application is not intended to be limited to the particular forms disclosed. Rather, the application is to cover all modifications, equivalents, and alternatives falling within the spirit and scope of the application as defined by the following appended claims.

1. A method of making chip slapper detonators, comprising the steps of:
providing a substrate having a substrate top and a substrate bottom;
electroplating a pattern of conductive pads on said substrate bottom;
drilling a pattern of via holes through said substrate, wherein said via holes are in contact with said conductive pads;
plating said via holes with a conductive material to create a conductive path in said via holes between said substrate top and said substrate bottom;
metallization of a multiplicity of conductive bridges on said substrate top;
adhering a slapper layer over said multiplicity conductive bridges on said substrate; and
dicing said substrate into individual chip slapper detonators wherein each said individual chip slapper detonator includes one of said multiplicity conductive bridges.

2. The method of making chip slapper detonators of claim 1 wherein said step of providing a substrate comprises providing an alumina wafer substrate.

3. The method of making chip slapper detonators of claim 1 wherein said step of electroplating a pattern of conductive pads on said substrate bottom comprises electroplating a pattern of conductive gold pads on said substrate bottom.

4. The method of making chip slapper detonators of claim 1 wherein said step of plating said via holes with a conductive material comprises plating said via holes with a conductive gold material.

5. The method of making chip slapper detonators of claim 1 wherein said step of metallization of a multiplicity conductive bridges on said substrate top comprises depositing said multiplicity conductive bridges on said substrate top using e-beam vapor deposition.

6. The method of making chip slapper detonators of claim 1 wherein said step of adhering a slapper layer over said multiplicity conductive bridges on said substrate comprises adhering a slapper layer over said multiplicity conductive bridges on said substrate in a vacuum system.

7. The method of making chip slapper detonators of claim 1 wherein said step of adhering a slapper layer over said multiplicity conductive bridges on said substrate comprises adhering a polyimide slapper layer over said multiplicity conductive bridges.

8. The method of making chip slapper detonators of claim 1 further comprising the step of depositing a gold layer over said slapper layer over said multiplicity conductive bridges on said substrate.

9. A method of making chip slapper detonators, comprising the steps of:
providing a substrate having a substrate top and a substrate bottom;
patterning said substrate bottom with a multiplicity of conductive pads;
laser drill a pattern of via holes through said substrate, wherein said via holes are in contact with said conductive pads;
plate said via holes with gold to create a conductive path in said via holes between said substrate top and said substrate bottom;
position a shadow mask on said on said substrate top, wherein said shadow mask will determine the shape of a multiplicity of conductive bridges on said substrate;
depositing said multiplicity conductive bridges on said substrate top;
adhering a slapper layer over said multiplicity conductive bridges on said substrate; and
diced said substrate into individual chip slapper detonators wherein each said individual chip slapper detonator includes one of said multiplicity conductive bridges.

10. The method of making chip slapper detonators of claim 9 wherein said step of providing a substrate comprises providing an alumina wafer substrate.

11. The method of making chip slapper detonators of claim 9 wherein said step of patterning said substrate bottom with a multiplicity of conductive pads comprises patterning said substrate bottom with a multiplicity of gold pads.

12. The method of making chip slapper detonators of claim 9 wherein said step of depositing said multiplicity conductive bridges on said substrate top comprises depositing said multiplicity conductive bridges on said substrate top using e-beam vapor deposition.

13. The method of making chip slapper detonators of claim 9 wherein said step of adhering a slapper layer over said multiplicity conductive bridges on said substrate comprises adhering a slapper layer over said multiplicity conductive bridges on said substrate in a vacuum system.

14. The method of making chip slapper detonators of claim 9 wherein said step of adhering a slapper layer over said multiplicity conductive bridges on said substrate comprises adhering a Kapton slapper layer over said multiplicity conductive bridges.

15. The method of making chip slapper detonators of claim 9 further comprising the step of depositing a gold layer over said slapper layer over said multiplicity conductive bridges on said substrate.

16. A method of making chip slapper detonators, comprising the steps of:
providing an alumina wafer substrate having a substrate top and a substrate bottom;
patterning said substrate bottom with a multiplicity of conductive gold pads;
laser drill a pattern of via holes through said substrate, wherein said via holes are in contact with said conductive pads;
plate said via holes with gold to create a conductive path in said via holes between said substrate top and said conductive gold pads on said substrate bottom;
position a shadow mask on said on said substrate top, wherein said shadow mask will determine the shape of a multiplicity of conductive bridges on said substrate;
depositing said multiplicity conductive bridges on said substrate top;
adhering a slapper layer over said multiplicity conductive bridges on said substrate; and
diced said substrate into individual chip slapper detonators wherein each said individual chip slapper detonator includes one of said multiplicity conductive bridges.

17. The method of making chip slapper detonators of claim 16 wherein said step of depositing said multiplicity conductive bridges on said substrate top comprises depositing said multiplicity conductive bridges on said substrate top using e-beam vapor deposition.

18. The method of making chip slapper detonators of claim 16 wherein said step of adhering a slapper layer over said multiplicity conductive bridges on said substrate comprises adhering a slapper layer over said multiplicity conductive bridges on said substrate in a vacuum system.

19. The method of making chip slapper detonators of claim 16 wherein said step of adhering a slapper layer over said multiplicity conductive bridges on said substrate comprises adhering a Kapton slapper layer over said multiplicity conductive bridges.

20. The method of making chip slapper detonators of claim 16 further comprising the step of depositing a gold layer over said slapper layer over said multiplicity conductive bridges on said substrate.
